(19) United States
(12) Patent Application Publication
(10) Pub. No.: US 2022/0011483 A1
(43) Pub. Date: Jan. 13, 2022

(54) WAVELENGTH CONVERSION MEMBER AND LIGHT EMITTING DEVICE

(71) Applicant: NIPPON ELECTRIC GLASS CO., LTD., Otsu-shi, Shiga (JP)

(72) Inventors: Shotaro FUKUMOTO, Otsu-shi (JP); Tadahito FURUYAMA, Otsu-shi (JP); Shunsuke FUJITA, Otsu-shi (JP)

(21) Appl. No.: 17/293,940

(22) PCT Filed: Dec. 19, 2019
(86) PCT No.: PCT/JP2019/049764

§ 371 Date: May 14, 2021

(30) Foreign Application Priority Data
Dec. 27, 2018 (JP) 2018-244763
Dec. 13, 2019 (JP) 2019-225084

(51) Int. Cl. G02B 5/20; H01L 33/50; H01S 5/02257

(52) U.S. Cl. CPC G02B 5/206; H01S 5/02257; H01L 33/502

(57) ABSTRACT

The present invention has an object of providing a wavelength conversion member and a light emitting device which have a high luminescence intensity. A wavelength conversion member 10 contains phosphor particles 2 in a matrix 1 and has a haze value of 0.7 to 0.999 in a visible wavelength range where an excitation spectrum of the phosphor particles 2 shows a spectral intensity of 5% or less of a maximum peak intensity.

### TECHNICAL FIELD

The present invention relates to wavelength conversion members for converting the wavelength of light emitted from light emitting diodes (LEDs), laser diodes (LDs) or the like to another wavelength, and light emitting devices.

### BACKGROUND ART

Recently, attention has been increasingly focused on light emitting devices using LEDs or LDs as next-generation light emitting devices to replace fluorescence lamps and incandescent lamps, from the viewpoint of their low power consumption, small size, light weight, and easy adjustment to light intensity. As examples of such next-generation light emitting devices, light emitting devices are disclosed in which a wavelength conversion member is disposed on an LED capable of emitting a blue light and absorbs part of the blue light to convert it to a yellow light (Patent Literatures 1 and 2). These light emitting devices emit a white light which is a synthetic light of the blue light (excitation light) emitted from the LED and the yellow light (fluorescence) emitted from the wavelength conversion member.

### CITATION LIST

### Patent Literature

### [PTL 1]

JP-A-2000-208815

### [PTL 2]

JP-A-2003-258308

### SUMMARY OF INVENTION

### Technical Problem

In recent years, with the increasing performance of light emitting devices, there is a demand for a wavelength conversion member that enables extraction of a higher-intensity white light. However, with the use of conventional wavelength conversion members, a problem arises that a synthetic light of excitation light and fluorescence extracted to the outside has an insufficient luminous flux and, therefore, the luminescence intensity cannot sufficiently be increased.

In view of the foregoing, the present invention has an object of providing a wavelength conversion member and a light emitting device which have a high luminescence intensity.

### Solution to Problem

The inventors conducted intensive studies and, as a result, found that the luminous flux of a synthetic light of excitation light and fluorescence extracted from a wavelength conversion member can be improved by adjusting the haze value of the wavelength conversion member in a specific wavelength range.

Specifically, a wavelength conversion member according to the present invention is a wavelength conversion member containing phosphor particles in a matrix and has a haze value of 0.7 to 0.999 in a visible wavelength range where an excitation spectrum of the phosphor particles shows a spectral intensity of 5% or less of a maximum peak intensity.

In the wavelength conversion member according to the present invention, the matrix is preferably glass.

In the wavelength conversion member according to the present invention, the phosphor particles may be phosphor particles that absorb part of fluorescence. With the use of such phosphor particles, the effects of the present invention can be easily given.

In the wavelength conversion member according to the present invention, the phosphor particles are preferably particles of a garnet-based ceramic phosphor.

The wavelength conversion member according to the present invention preferably contains a light-scattering material.

The wavelength conversion member according to the present invention preferably has a thickness of 1000 μm or less.

A light emitting device according to the present invention includes: the above-described wavelength conversion member; and a light source operable to irradiate the wavelength conversion member with excitation light.

In the light emitting device according to the present invention, the light source is preferably a light emitting diode or a laser diode.

### Advantageous Effects of Invention

The present invention enables provision of a wavelength conversion member and a light emitting device which have a high luminescence intensity.

### BRIEF DESCRIPTION OF DRAWINGS

FIG. 1 is a schematic cross-sectional view showing a wavelength conversion member according to one embodiment of the present invention.

FIG. 2 is a view for illustrating a decrease in luminous flux of synthetic light in a wavelength conversion member having a high haze value.

FIG. 3 is a view for illustrating a decrease in luminous flux of synthetic light in a wavelength conversion member having a low haze value.

FIG. 4 is a schematic graph representing an excitation spectrum and a fluorescence spectrum of YAG phosphor particles.

FIG. 5 is a schematic cross-sectional view showing a light emitting device according to one embodiment of the present invention.

FIG. 6 is a graph showing the relation between relative luminous flux and haze in examples of the present invention.

### DESCRIPTION OF EMBODIMENTS

Hereinafter, embodiments of the present invention will be described in detail with reference to the drawings. However, the present invention is not at all limited to the following embodiments.

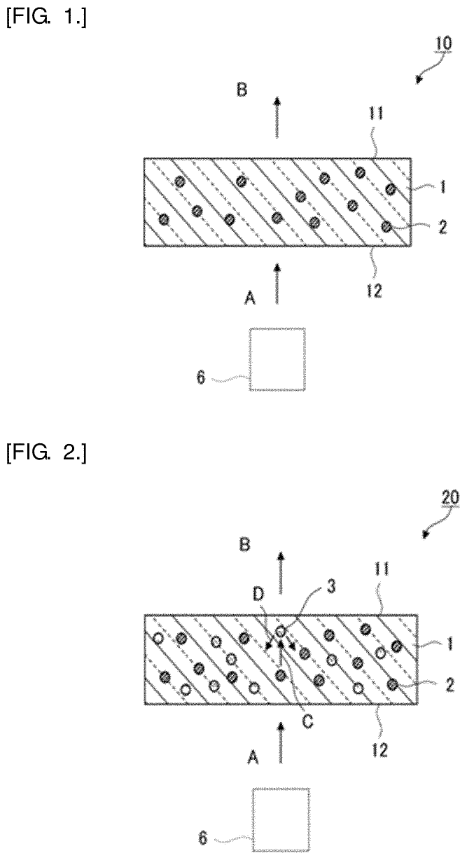

(Wavelength Conversion Member 10) FIG. 1 is a schematic cross-sectional view showing a wavelength conversion member according to an embodiment of the present invention. As shown in FIG. 1, the wavelength conversion member 10 contains phosphor particles 2 in a matrix 1. Furthermore, the wavelength conversion member 10 has a first principal surface 11 and a second principal surface 12.

As shown in FIG. 1, excitation light A emitted from a light source 6 enters the wavelength conversion member 10 through the second principal surface 12. Thus, the phosphor particles 2 are irradiated with the excitation light A, so that fluorescence is emitted from the phosphor particles 2. Then, a synthetic light B of the excitation light A and the fluorescence is emitted from the wavelength conversion member 10 through the first principal surface 11.

The wavelength conversion member 10 has a haze value of 0.7 to 0.999 in a visible wavelength range where an excitation spectrum of the phosphor particles 2 shows a spectral intensity of 5% or less of the maximum peak intensity. In the present invention, the visible wavelength range refers to a range from 380 nm to 780 nm. The haze value is calculated based on the following formula from the values of the total light transmittance and diffuse transmittance in the above visible wavelength range.

Haze value=(Diffuse Transmittance)/(Total Light Transmittance)

The inventors conducted intensive studies and, as a result, found that in the wavelength conversion member 10 containing phosphor particles 2 in a matrix 1, the luminous flux of a synthetic light B extracted from the first principal surface 11 can be improved by adjusting the haze value in a visible wavelength range where the excitation spectrum of the phosphor particles 2 shows a spectral intensity of 5% or less of the maximum peak intensity. The mechanism can be explained as follows.

FIG. 2 is a view for illustrating a decrease in luminous flux of synthetic light in a wavelength conversion member having a high haze value. A wavelength conversion member 20 shown in FIG. 2 contains phosphor particles 2 and a light-scattering material 3 in a matrix 1. Because the wavelength conversion member 20 has a large content of the light-scattering material 3, it has a high haze value. In such a wavelength conversion member 20, excitation light A and fluorescence C are excessively scattered by the light-scattering material 3 and are therefore likely to become return light D. Therefore, the synthetic light B is less likely to be emitted from the first principal surface 11, so that the luminous flux of the synthetic light B is likely to decrease.

In view of the above problem, in the present invention, the upper limit of the haze value is defined. Specifically, the upper limit of the haze value of the wavelength conversion member 10 is preferably 0.999 or less, more preferably 0.995 or less, and particularly preferably 0.99 or less. Thus, excessive scattering of excitation light A and fluorescence C can be reduced, so that the decrease in luminous flux of synthetic light B emitted from the first principal surface 11 can be reduced.

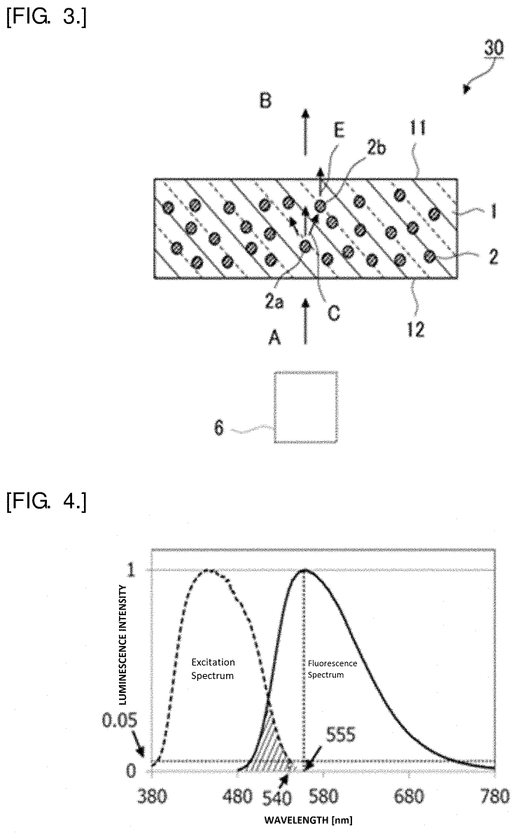

FIG. 3 is a view for illustrating a decrease in luminous flux of synthetic light in a wavelength conversion member having a low haze value. A wavelength conversion member 30 shown in FIG. 3 contains phosphor particles 2 in a matrix 1, but contains no light-scattering material 3, and, therefore, has a low haze value. Generally, since, in a wavelength conversion member 30 without any light-scattering material 3, excitation light A is less likely to be scattered in the matrix 1, the amount of excitation light A applied to the phosphor particles 2 per unit area is relatively small, so that the intensity of fluorescence emitted is likely to decrease. Therefore, in the wavelength conversion member 30, the content of the phosphor particles 2 is increased in order to obtain a desired chromaticity. However, if the content of the phosphor particles 2 increases, absorption of part of fluorescence by the phosphor particles 2 themselves, i.e., so-called fluorescence reabsorption, is likely to occur. Specifically, as shown in FIG. 3, fluorescence C emitted from a phosphor particle 2a is absorbed by another phosphor particle 2b existing near the phosphor particle 2a and is emitted as new fluorescence E from the other phosphor particle 2b. Since, thus, energy loss due to wavelength conversion occurs, the intensity of the fluorescence E is lower than that of the fluorescence C. Therefore, if fluorescence reabsorption occurs, the intensity of fluorescence emitted from the first principal surface 11 decreases, so that the luminous flux of the synthetic light B also decreases.

In view of the above problem, in the present invention, the lower limit of the haze value is defined. Specifically, the lower limit of the haze value of the wavelength conversion member 10 is preferably 0.7, more preferably 0.75 or more, and particularly preferably 0.80 or more. Thus, fluorescence reabsorption can be reduced, so that the decrease in luminous flux of synthetic light B emitted from the first principal surface 11 can be reduced.

Furthermore, the haze value adopted in the present invention is a value measured in a visible wavelength range where the excitation spectrum of the phosphor particles 2 shows a spectral intensity of 5% or less of the maximum peak intensity. The visible wavelength range is defined as 380 nm to 780 nm. The excitation spectrum is a spectrum showing how the fluorescence intensity of the phosphor in a specific wavelength (monitoring wavelength) changes with changes in wavelength of excitation light. Although an arbitrary wavelength can be selected as the monitoring wavelength, a wavelength giving a maximum fluorescence intensity of the phosphor particles 2 is generally selected as the monitoring wavelength.

For example, when the phosphor particles 2 are irradiated with light of a wavelength giving a maximum spectral intensity of the excitation spectrum, the probability of excitation of the phosphor particles 2 is high, so that the intensity of fluorescence emitted from the phosphor particles 2 at the monitoring wavelength reaches a maximum value. On the other hand, when the phosphor particles 2 are irradiated with light of a wavelength giving a low spectral intensity, the probability of excitation of the phosphor particles 2 is low, so that the fluorescence intensity of the phosphor particles 2 is low. When the phosphor particles 2 are irradiated with light of a wavelength giving a lower spectral intensity, the phosphor particles 2 are not excited, so that no fluorescence is emitted.

FIG. 4 is a schematic graph representing an excitation spectrum and a fluorescence spectrum of YAG phosphor particles. The broken line shows the excitation spectrum (monitoring wavelength: 555 nm) and the solid line shows the fluorescence spectrum. The luminescence intensities of the excitation spectrum and the fluorescence spectrum are expressed as values relative to the maximum spectral intensity of each spectrum assumed to be 1. As shown in FIG. 4, the YAG phosphor particles have its excitation spectrum in a wavelength range of 380 nm to 540 nm. Therefore, light absorption, including fluorescence reabsorption, occurs in this wavelength range. In the wavelength range where light absorption occurs, there arises a problem that the spectral shapes of the total light transmittance and the diffuse transmittance are likely to vary due to the effects of scattering factors which will be described hereinafter, and, therefore, a correlation between haze value and luminescence intensity is difficult to establish.

On the other hand, as described previously, when the phosphor particles 2 are irradiated with light having a wavelength range where the excitation spectrum shows a sufficiently low spectral intensity, the phosphor particles 2 are less likely to be excited, so that fluorescence is less likely to be emitted. In the present invention, as such a wavelength range, a visible wavelength range (540 nm to 780 nm in the example of FIG. 4) where the maximum peak intensity in the excitation spectrum is 5% or less is defined. The inventors found from the above that, in the defined wavelength range, the wavelength conversion member is free from the effects of light absorption and the like and the correlation between haze value and luminous flux can be established, and completed the present invention.

The haze value is sufficient if it falls between 0.7 and 0.999 in part of the visible wavelength range where the maximum peak intensity in the excitation spectrum is 5% or less, but it is particularly preferred that the haze value falls between 0.7 and 0.999 throughout the above visible wavelength range.

There is no particular limitation as to the shape of the wavelength conversion member 10, but the shape is generally a sheet-like shape (such as a rectangular sheet-like shape or a disc-like shape). The thickness of the wavelength conversion member 10 can be appropriately selected to obtain a desired chromaticity, but, specifically, is preferably 1000 μm or less, more preferably 800 μm or less, and particularly preferably 500 μm or less. If the thickness is too large, the luminous flux of the synthetic light B may decrease. The lower limit of the thickness of the wavelength conversion member 10 is preferably about 50 μm. If the thickness is too small, the mechanical strength is likely to decrease.

There is no particular limitation as to the chromaticity of the wavelength conversion member 10. However, in using YAG phosphor particles capable of emitting a yellow light as the phosphor particles 2 and using a blue light (having a central wavelength of around 450 nm) as the excitation light A, the synthetic light B emitted from the wavelength conversion member 10 preferably has the following chromaticity. Specifically, when collecting the synthetic light B obtained by irradiating the wavelength conversion member 10 placed in the opening of an integrating sphere with the excitation light A and measuring the collected synthetic light B with a spectrometer, the chromaticity (Cx) is preferably 0.22 to 0.44, more preferably 0.23 to 0.37, and particularly preferably 0.24 to 0.33. If the chromaticity of the synthetic light B is too low, the proportion of the blue light becomes excessively high, so that a desired color tone is difficult to obtain. Furthermore, in such cases, the amount of phosphor particles 2 added is often small, so that the specified haze value is also difficult to obtain. On the other hand, if the chromaticity of the synthetic light B is too high, the proportion of the yellow light becomes excessively high, so that a desired color tone is difficult to obtain. Furthermore, in such cases, the amount of phosphor particles 2 added is often large, so that the luminous flux is likely to be decreased by the effect of fluorescence reabsorption.

In the visible wavelength range where the maximum intensity in the excitation spectrum of the phosphor particles 2 is 5% or less, the total light transmittance of the wavelength conversion member 10 is preferably 20% or more, more preferably 30% or more, and particularly preferably 40% or more. If the total light transmittance is too low, the luminous flux of the synthetic light B emitted from the first principal surface 11 excessively decreases, so that the luminescence intensity of the wavelength conversion member 10 decreases.

In the present invention, the haze value can be adjusted at an arbitrary value by changing scattering factors constituting the wavelength conversion member 10. More specifically, the haze value can be adjusted by changing the refractive index of the matrix 1 and the respective contents, particle diameters, refractive indices, and so on of the phosphor particles 2 and the light-scattering material 3. A detailed description will be given below of each of the scattering factors.

(Matrix 1)

There is no particular limitation as to the type of the matrix 1 in the present invention so long as it is a transparent material that can contain phosphor particles 2 in its inside and transmits the excitation light A and the synthetic light B. For example, resin or glass can be used. From the viewpoint of obtaining a wavelength conversion member 10 having high thermal resistance and high weather resistance, glass is preferably used. On the other hand, from the viewpoint of obtaining a light wavelength conversion member 10, resin is preferably used.

Examples of the glass include SiO₂—B₂O₃-based glasses, SiO₂—B₂O₃—RO-based (where RO is an alkali metal oxide) glasses, SnO—P₂O₅-based glasses, TeO₂-based glasses, and Bi₂O₃-based glasses.

Preferred SiO₂—B₂O₃-based glasses are, for example, those having a composition containing, in terms of % by mole, 30 to 80% SiO₂, 1 to 40% B₂O₃, 0 to 10% MgO, 0 to 30% CaO, 0 to 20% SrO, 0 to 40% BaO, 5 to 45% MgO+CaO+SrO+BaO, 0 to 20% Al₂O₃, and 0 to 20% ZnO.

Preferred SiO₂—B₂O₃—RO-based glasses are, for example, those having a composition containing, in terms of % by mole, 70 to 90% SiO₂, 9 to 25% B₂O₃, 0 to 5% Li₂O, 0 to 5% Na₂O, 0 to 5% K₂O, 0.1 to 5% Li₂O+Na₂O+K₂O, 0 to 5% Al₂O₃, 0 to 5% MgO, and 0 to 5% CaO+SrO+BaO.

Preferred SnO—P₂O₅-based glasses are those having a glass composition containing, in terms of % by mole, 35 to 80% SnO, 5 to 40% P₂O₅, and 0 to 30% B₂O₃.

Examples of the resin that can be used include light-transmissive thermoplastic resins and thermosetting resins, and ultraviolet curable resins. Specific examples that can be used include polyvinyl chloride, polyvinylidene chloride, polyethylene terephthalate, polyvinyl alcohol, polystyrene, polycarbonate, acrylic resin, melamine resin, and epoxy resin. Particularly, polycarbonate or acrylic resin is preferably used because they have excellent light transmissivity.

The refractive index (nd) of the matrix 1 is preferably 1.3 to 2.2, more preferably 1.4 to 2.1, still more preferably 1.45 to 2.05, yet still more preferably 1.5 to 2, and particularly preferably 1.55 to 1.95. Thus, excessive scattering occurring at the interface between the phosphor particles 2 and the matrix 1 can be easily reduced, so that the haze value of the wavelength conversion member 10 can be easily adjusted.

As will be described hereinafter, the form of the matrix 1 is not particularly limited so long as it contains the phosphor particles 2 in its inside. For example, when the wavelength conversion member 10 is formed of a sintered body of glass powder and phosphor particles 2, the matrix 1 is formed of a sintered body of the glass powder. The average particle diameter (D₅₀) of the glass powder is preferably 0.1 km to 50 m, more preferably 0.5 μm to 40 μm, and particularly preferably 1 μm to 30 μm. If the average particle diameter (D₅₀) is too small, the effect of the grain boundaries, which constitute one of the scattering factors, is likely to be significant, so that the haze value may be excessively high. On the other hand, if the average particle diameter (D₅₀) is too large, the phosphor particles 2 are difficult to evenly disperse into the matrix 1, so that the chromaticity of the synthetic light B is likely to be uneven.

(Phosphor Particles 2)

The phosphor particles 2 may be phosphor particles that absorb part of fluorescence, in which case the effects of the present invention can be easily given. The phrase “absorb part of fluorescence” as used herein means that the excitation wavelength range and the luminescence wavelength range overlap with each other. Specifically, as shown in FIG. 4, the excitation spectrum has an overlap with the fluorescence spectrum in a wavelength range where the maximum peak intensity in the excitation spectrum is 5% or more.

The phosphor particles 2 preferably have a peak wavelength of the excitation spectrum within a range of wavelengths from 300 to 500 nm and a luminescence peak within a range of wavelengths from 380 to 780 nm, and are particularly preferably particles of a garnet-based ceramic phosphor, such as YAG (yttrium aluminum garnet) phosphor particles. However, the type of the phosphor particles 2 is not limited to the above and other examples that can be used include oxides, nitrides, oxynitrides, sulfides, oxysulfides, rare-earth sulfides, aluminate chlorides, and halophosphate.

The content of the phosphor particles 2 in the wavelength conversion member 10 is, in terms of % by volume, preferably 0.01 to 30%, more preferably 0.1 to 20%, and particularly preferably 1 to 15%. If the content of them is too large, the above-described fluorescence reabsorption is likely to occur, so that the luminescence intensity of the wavelength conversion member 10 is likely to decrease. If the content of them is too small, the color tone of the synthetic light B is likely to be inhomogeneous and a desired chromaticity is difficult to obtain.

The average particle diameter (D₅₀) of the phosphor particles 2 is preferably 0.001 to 50 μm, more preferably 0.1 to 30 μm, and particularly preferably 1 to 30 μm. If the average particle diameter of the phosphor particles 2 is too small, the phosphor particles 2 are likely to agglomerate together, so that the chromaticity of the synthetic light B may be uneven. In addition, scattering is likely to be excessive, so that the haze value may be excessively high. Also if the average particle diameter is too large, the phosphor particles 2 are difficult to evenly disperse into the matrix 1, so that the chromaticity of the synthetic light B may be uneven.

In the present invention, the average particle diameter (D₅₀) of powdered particles means a value measured by laser diffractometry and indicates the particle diameter when in a volume-based cumulative particle size distribution curve as determined by laser diffractometry the integrated value of cumulative volume from the smaller particle diameter is 50%. On the other hand, the particle diameter of particles in the wavelength conversion member 10 (for example, the average particle diameter of the phosphor particles 2 being dispersed in the matrix 1) can be measured, for example, with an X-ray CT scan. In this case, the average particle diameter is the particle diameter when in a volume-based cumulative particle size distribution curve as measured by the CT scan the integrated value of cumulative volume from the smaller particle diameter is 50%.

There is no particular limitation as to the refractive index (nd) of the phosphor particles 2, but, generally, the powder of the phosphor particles 2 often has a higher refractive index than the resin or glass forming the matrix 1. For example, the refractive index of borosilicate glass is about 1.5 to about 1.6, whereas the refractive index of YAG phosphor particles is about 1.83. If the refractive index difference between the phosphor particles 2 and the matrix 1 is too large, the excitation light A is highly likely to be reflected at the interface between the phosphor particles 2 and the matrix 1, so that the haze value is likely to be excessively high. Therefore, the refractive index difference between the matrix 1 and the phosphor particles 2 is preferably 0.5 or less, more preferably 0.4 or less, still more preferably 0.3 or less, and particularly preferably 0.25 or less. Thus, excessive scattering occurring at the interface between the phosphor particles 2 and the matrix 1 can be easily reduced, so that the haze value of the wavelength conversion member 10 can be easily adjusted. However, the refractive index difference is not necessarily limited to the above.

A preferred range of haze values to maximize the luminous flux correlates with the refractive index difference between the matrix 1 and the phosphor particles 2. Specifically, the refractive index difference between the matrix 1 and the phosphor particles 2 and the haze value are preferably controlled as follows.

(1) When the refractive index difference between the matrix 1 and the phosphor particles 2 is 0.5 to 0.35, the haze value is preferably 0.7 to 0.99, more preferably 0.72 to 0.9, and particularly preferably 0.7 to 0.85.

(2) When the refractive index difference between the matrix 1 and the phosphor particles 2 is below 0.35 to 0.25, the haze value is preferably 0.7 to 0.99, more preferably 0.75 to 0.95, and particularly preferably 0.8 to 0.9.

(3) When the refractive index difference between the matrix 1 and the phosphor particles 2 is below 0.25, the haze value is preferably 0.7 to 0.999, more preferably 0.8 to 0.995, and particularly preferably 0.9 to 0.99.

(Light-Scattering Material 3)

The wavelength conversion member 10 according to the present invention preferably contains a light-scattering material 3. There is no particular limitation as to the type of the light-scattering material 3 and inorganic particles, such as ceramic powder or glass powder, can be used. Particularly, ceramic powder is preferably used. Ceramic powder generally has higher thermal diffusivity than the transparent material, such as resin or glass, forming the matrix 1 and, therefore, can efficiently release heat produced by the phosphor particles 2 when emitting fluorescence to the outside of the wavelength conversion member 10 and can reduce thermal degradation of the phosphor particles 2. On the other hand, glass powder allows for easy fine adjustment of the refractive index and is therefore preferred in terms of ease of close adjustment of the haze value of the wavelength conversion member 10.

Examples of the ceramic powder that can be used include silicon dioxide, boron nitride, aluminum nitride, aluminum oxide, magnesium oxide, titanium oxide, niobium oxide, and zinc oxide.

Examples of the glass powder that can be used include multicomponent glasses and single-component glasses, such as silica glass. In heating a mixture of the matrix 1 and the light-scattering material 3 in a below-described process for producing the wavelength conversion member 10, if the glass powder as the light-scattering material 3 is softened and flowed, its particle diameter changes, so that a desired haze value may be difficult to obtain. Therefore, the softening point of the glass powder is, compared to the softening point of the matrix 1, preferably 30° C. or more than 30° C. higher, more preferably 50° C. or more than 50° C. higher, and particularly preferably 100° C. or more than 100° C. higher.

The content of the light-scattering material 3 in the wavelength conversion member 10 is, in terms of % by volume, preferably 0 to 50%, more preferably 0.01 to 40%, still more preferably 0.1 to 10%, and particularly preferably 1 to 5%. If the content of the light-scattering material 3 is too large, the haze value of the wavelength conversion member 10 becomes excessively high, so that the luminescence intensity is likely to decrease. In addition, the total light transmittance of the wavelength conversion member 10 may excessively decrease.

The average particle diameter (D₅₀) of the light-scattering material 3 is preferably 0.1 μm to 100 μm, more preferably 0.3 μm to 50 μm, and particularly preferably 1 μm to 30 μm. If the average particle diameter (D₅₀) of the light-scattering material 3 is too small, the haze value is likely to be excessively high. In addition, scattering is likely to be excessive, so that the haze value may be excessively high. On the other hand, if the average particle diameter (D₅₀) of the light-scattering material 3 is too large, the light-scattering material 3 is difficult to evenly disperse into the matrix 1, so that the chromaticity of the synthetic light B may be uneven.

There is no particular limitation as to the shape of the light-diffusing material 3 and examples include a spherical shape, a crushed shape, a hollow shape, a rod-like shape, and a fibrous shape.

The refractive index difference between the light-scattering material 3 and the matrix 1 is preferably 0.5 or less, more preferably 0.4 or less, and particularly preferably 0.3 or less. Thus, excessive scattering occurring at the interface between the light-scattering material 3 and the matrix 1 can be easily reduced, so that the haze value of the wavelength conversion member 10 can be easily adjusted. However, the refractive index difference is not necessarily limited to the above.

The density difference between the phosphor particles 2 and the matrix 1 is preferably 4 or less, more preferably 3.5 or less, and particularly preferably 3 or less. If the density difference is too large, the phosphor particles 2 are difficult to evenly disperse into the matrix 1, so that the chromaticity of the synthetic light B is likely to be uneven. On the other hand, the density difference between the light-scattering material 3 and the matrix 1 is preferably 4 or less, more preferably 3.5 or less, and particularly preferably 3 or less. If the density difference is too large, the light-scattering material 3 is difficult to evenly disperse into the matrix 1, so that the chromaticity of the synthetic light B is likely to be uneven.

Other than the above-described scattering factors, voids, grain boundaries, striae and the like in the wavelength conversion member 10 may have effects on the haze value as scattering factors. Furthermore, when glass is used for the matrix 1, crystals may precipitate in the below-described process for producing the wavelength conversion member 10, in which case the crystals may be a scattering factor. Also by considering these scattering factors, the haze value can be adjusted at an arbitrary value.

The voidage of the wavelength conversion member 10 is, in terms of % by volume, preferably 5% or less, more preferably 3% or less, and particularly preferably 1% or less. If the voidage is too high, light scatters at the boundaries between the voids and the matrix 1, so that scattering is likely to be excessive.

When the matrix 1 is made of glass, the amount of crystals precipitated in the inside of the matrix 1 is, in terms of % by volume relative to the matrix 1, preferably 30% or less, more preferably 25% or less, and particularly preferably 20% or less. If the amount of crystals is too large, light scattering excessively occurs, so that the luminescence intensity of the wavelength conversion member 10 is likely to decrease. In addition, the total light transmittance of the wavelength conversion member 10 may excessively decrease.

The above voidage and percentage by volume of crystals can be measured with a CT scan.

There is no particular limitation as to the production method of the wavelength conversion member 10 so long as the wavelength conversion member 10 has a structure containing phosphor particles 2 inside of a matrix 1. For example, the wavelength conversion member 10 can be obtained by mixing glass powder and phosphor particles 2 (and additionally a light-scattering material 3 as necessary) and firing them. In particular, it is preferred to obtain the wavelength conversion member 10 by pressing the mixture of glass powder and phosphor particles 2 to make a preform and then firing the preform. Meanwhile, the sintered body of the glass powder and the phosphor particles 2 is significantly susceptible to the effect of the grain boundaries which constitute one of the scattering factors. Therefore, from the viewpoint of producing a wavelength conversion member 10 less susceptible to the effect of the grain boundaries, it is preferred to produce the wavelength conversion member 10 by containing phosphor particles 2 into liquid or semisolid resin and then curing the resin.

(Light Emitting Device)

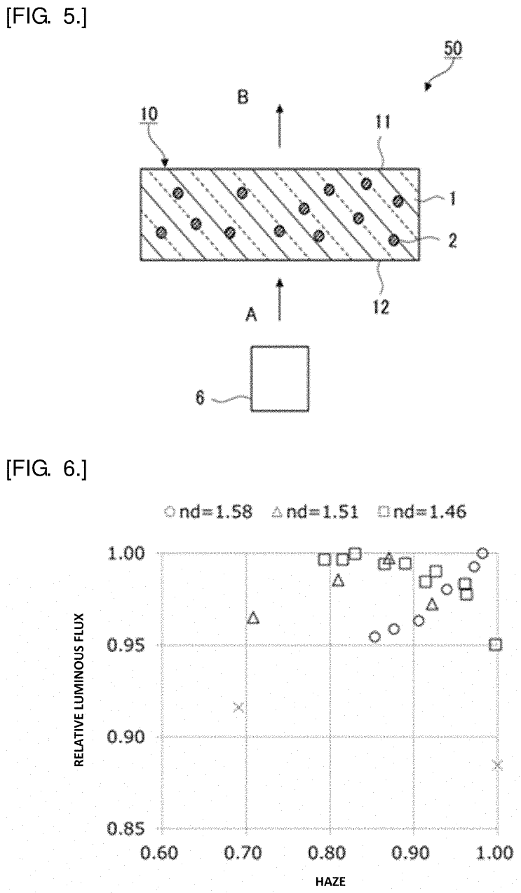

FIG. 5 is a schematic cross-sectional view showing a light emitting device according to an embodiment of the present invention. As shown in FIG. 5, a light emitting device 50 includes the wavelength conversion member 10 and a light source 6. In this embodiment, the light source 6 is disposed so that excitation light A enters the second principal surface 12. The excitation light A emitted from the light source 6 is converted in wavelength to fluorescence having a longer wavelength than the excitation light A by the wavelength conversion member 10. Furthermore, part of the excitation light A passes through the wavelength conversion member 10. Therefore, the wavelength conversion member 10 emits a synthetic light B composed of the excitation light A and the fluorescence. For example, when the excitation light A is a blue light and the fluorescence is a yellow light, a white synthetic light B can be provided.

Examples of the light source 6 include an LED and an LD. However, from the viewpoint of increasing the luminescence intensity of the light emitting device 10, an LD, which is capable of emitting high-intensity light, is preferably used as the light source 6. Although in this embodiment the light source 6 is disposed away from the wavelength conversion member 10, the placement of the light source 6 is not limited to this. For example, the light source 6 and the wavelength conversion member 10 may be joined together in direct contact or through an adhesive layer.

### Examples

Hereinafter, the wavelength conversion member according to the present invention will be described in detail with reference to examples, but the present invention is not limited to the following examples.

Tables 1 to 3 show working examples (Nos. 1 to 6 and 9 to 23) of the present invention and comparative examples (Nos. 7 and 8).

TABLE 1

| | | No. 1 | No. 2 | No. 3 | No. 4 | No. 5 | No. 6 | No. 7 | No. 8 |
|---|---|---|---|---|---|---|---|---|---|
| MATRIX | Type | Glass A | Glass A | Glass A | Glass A | Glass A | Glass A | Glass A | Resin C |
| | Refractive Index | 1.58 | 1.58 | 1.58 | 1.58 | 1.58 | 1.58 | 1.58 | 1.58 |
| PHOSPHOR | Type | YAG | YAG | YAG | YAG | YAG | YAG | YAG | YAG |
| | Refractive Index | 1.82 | 1.82 | 1.82 | 1.82 | 1.82 | 1.82 | 1.82 | 1.82 |
| | Volume Concentration (%) | 10.6 | 10.3 | 9.2 | 8.3 | 6.5 | 5.7 | 2.0 | 10.8 |
| LIGHT-SCATTERING | Type | — | Alumina | Alumina | Alumina | Alumina | Alumina | Alumina | — |
| MATERIAL | Volume Concentration (%) | — | 0.1 | 0.4 | 0.8 | 1.5 | 2.0 | 8.0 | — |

| | | | | | | | | |
|---|---|---|---|---|---|---|---|---|
| Refractive Index Difference between Matrix and Phosphor | 0.24 | 0.24 | 0.24 | 0.24 | 0.24 | 0.24 | 0.24 | 0.24 |
| Thickness/μm | 200 | 200 | 200 | 200 | 200 | 200 | 200 | 200 |
| Haze value | 0.854 | 0.876 | 0.906 | 0.939 | 0.972 | 0.982 | 1.000 | 0.691 |
| Luminous Flux (a.u.) | 0.95 | 0.96 | 0.96 | 0.98 | 0.99 | 1.00 | 0.88 | 0.92 |
| Chromaticity Cx | 0.291 | 0.290 | 0.287 | 0.288 | 0.291 | 0.290 | 0.292 | 0.289 |

TABLE 2

| | | No. 9 | No. 10 | No. 11 | No. 12 | No. 13 | No. 14 | No. 15 | No. 16 |
|---|---|---|---|---|---|---|---|---|---|
| MATRIX | Type | Glass B | Glass B | Glass B | Glass B | Glass B | Glass B | Glass B | Glass B |
| | Refractive Index | 1.46 | 1.46 | 1.46 | 1.46 | 1.46 | 1.46 | 1.46 | 1.46 |
| PHOSPHOR | Type | YAG | YAG | YAG | YAG | YAG | YAG | YAG | YAG |
| | Refractive Index | 1.82 | 1.82 | 1.82 | 1.82 | 1.82 | 1.82 | 1.82 | 1.82 |
| | Volume Concentration (%) | 9.2 | 8.3 | 7.6 | 6.5 | 4.9 | 8.0 | 7.3 | 6.8 |
| LIGHT-SCATTERING | Type | — | Alumina | Alumina | Alumina | Alumina | — | Alumina | Alumina |
| MATERIAL | Volume Concentration (%) | — | 0.2 | 0.4 | 0.8 | 2.0 | — | 0.1 | 0.2 |

| | | | | | | | | |
|---|---|---|---|---|---|---|---|---|
| Refractive Index Difference between Matrix and Phosphor | 0.36 | 0.36 | 0.36 | 0.36 | 0.36 | 0.36 | 0.36 | 0.36 |
| Thickness/μm | 200 | 200 | 200 | 200 | 200 | 180 | 180 | 180 |
| Haze value | 0.830 | 0.890 | 0.926 | 0.963 | 0.997 | 0.794 | 0.815 | 0.865 |
| Luminous Flux (a.u.) | 1.00 | 0.99 | 0.99 | 0.98 | 0.95 | 1.00 | 1.00 | 0.99 |
| Chromaticity Cx | 0.291 | 0.290 | 0.291 | 0.288 | 0.287 | 0.244 | 0.238 | 0.241 |

TABLE 3

| | | No. 17 | No. 18 | No. 19 | No. 20 | No. 21 | No. 22 | No. 23 |
|---|---|---|---|---|---|---|---|---|
| MATRIX | Type | Glass B | Glass B | Resin D | Resin E | Resin E | Resin E | Resin E |
| | Refractive Index | 1.46 | 1.46 | 1.46 | 1.51 | 1.51 | 1.51 | 1.51 |
| PHOSPHOR | Type | YAG | YAG | YAG | YAG | YAG | YAG | YAG |
| | Refractive Index | 1.82 | 1.82 | 1.82 | 1.82 | 1.82 | 1.82 | 1.82 |
| | Volume Concentration (%) | 6.0 | 5.0 | 10.2 | 12.7 | 9.9 | 8.8 | 6.7 |
| LIGHT-SCATTERING | Type | Alumina | Alumina | — | — | Alumina | Alumina | Alumina |
| MATERIAL | Volume Concentration (%) | 0.4 | 0.8 | — | — | 0.5 | 1.0 | 1.5 |

| | | | | | | | |
|---|---|---|---|---|---|---|---|
| Refractive Index Difference between Matrix and Phosphor | 0.36 | 0.36 | 0.36 | 0.31 | 0.31 | 0.31 | 0.31 |
| Thickness/μm | 180 | 180 | 180 | 200 | 200 | 200 | 200 |
| Haze value | 0.914 | 0.961 | 0.740 | 0.708 | 0.810 | 0.871 | 0.922 |
| Luminous Flux (a.u.) | 0.98 | 0.98 | 0.98 | 0.96 | 0.99 | 1.00 | 0.97 |
| Chromaticity Cx | 0.241 | 0.241 | 0.239 | 0.287 | 0.289 | 0.293 | 0.290 |

Each of Working Examples (Nos. 1 to 6 and 9 to 23) and Comparative Examples (Nos. 7 and 8) was produced in the following manner. First, a matrix, phosphor particles, and, if necessary, a light-scattering material were mixed to give their contents shown in Tables 1 to 3, thus obtaining a mixture. The materials below were used in the examples. In Table 1, the volume concentration (%)” indicates a volume concentration in the total volume of the matrix, the phosphor particles, and the light-scattering material.

(a) Matrix

Glass A powder—borosilicate glass (SiO₂—B₂O₃-based glass), refractive index (nd): 1.58, density: 3.1 g/cm³, average particle diameter D₅₀: 2.5 μm, softening point: 850° C.

Glass B powder—alkali borosilicate glass (SiO₂—B₂O₃—RO-based glass), refractive index (nd): 1.46, density: 2.1 g/cm³, average particle diameter D₅₀: 2.5 μm, softening point: 825° C.

Resin C—photocurable resin, refractive index (nd): 1.58, density: 2.4 g/cm³

Resin D—silicone resin, refractive index (nd): 1.46, density: 2.0 g/cm³

Resin E—photocurable resin, refractive index (nd): 1.51, density: 2.4 g/cm³

(b) Phosphor particles, YAG—Y3Al₅O₁₂, refractive index (nd): 1.82, average particle diameter D₅₀: 25 μm, density: 4.8 g/cm³

(c) Light-scattering material, alumina—Al₂O₃, average particle diameter: 1 μm, density: 4.0 g/cm³

As for Nos. 1 to 7 and 9 to 18, the mixture was put into a mold and pressed at a pressure of 0.20 MPa, thus obtaining a preform. Then, the preform was fired in the vicinity of the softening point of the glass, thus producing a glass sintered body.

As for Nos. 8, and 20 to 23, the mixture was put into a mold and cured by irradiation with ultraviolet light (having a central wavelength of 405 nm), thus producing a cured resin body.

As for No. 19, the mixture was put into a mold and cured by heating it at 40° C., thus producing a cured resin body.

The above glass sintered bodies and cured resin bodies were subjected to grinding and polishing processing, thus obtaining rectangular sheet-like wavelength conversion members having a thickness of 200 μm as for Nos. 1 to 13 and 20 to 23 or 180 μm as for Nos. 14 to 19.

The obtained wavelength conversion members were evaluated in terms of haze value, luminous flux, and chromaticity in the following manners.

The haze value was obtained by measuring the total light transmittance and diffuse transmittance with a spectro-photometer V-670 manufactured by JASCO Corporation and calculating the haze value at a wavelength of 600 nm based on the formula below. The spectral intensity at a wavelength of 600 nm in the excitation spectrum of the phosphor used in these examples was 5% or less of the maximum peak intensity.

Haze value=(Diffuse Transmittance)/(Total Light Transmittance)

The luminous flux and chromaticity were measured by irradiating the wavelength conversion member with excitation light from the light source and collecting emitted light from the wavelength conversion member with an integrating sphere. The light source used was a blue LED (the maximum peak of the excitation spectrum: 450 nm) and its power was kept constant. A spectrometer PMA-12 manufactured by Hamamatsu Photonics K.K. was used as the measuring device. In relation to the luminous flux, the value in Example No. 6 having exhibited the maximum value in all of Working Examples (Nos. 1 to 6 and 9 to 23) and Comparative Examples (Nos. 7 and 8) was assumed to be 1 and the values in other examples were expressed as relative values.

FIG. 6 shows a graph in which for each sample the haze value was plotted against the value of relative luminous flux.

As shown in Tables 1 to 3 and FIG. 6, in Working Examples (Nos. 1 to 6 and 9 to 23), wavelength conversion members exhibiting a high luminous flux and having a high luminescence intensity were obtained. Specifically, their relative luminous fluxes were 0.95 or more.

### REFERENCE SIGNS LIST

1 matrix
2 phosphor particle
2a phosphor particles
2b phosphor particles
3 light-scattering material
6 light source
10 wavelength conversion member
11 first principal surface
12 second principal surface
20 wavelength conversion member
30 wavelength conversion member
50 light emitting device
A excitation light
B synthetic light
C fluorescence
D returned light
E fluorescence

1: A wavelength conversion member containing phosphor particles in a matrix, the wavelength conversion member having a haze value of 0.7 to 0.999 in a visible wavelength range where an excitation spectrum of the phosphor particles shows a spectral intensity of 5% or less of a maximum peak intensity.

2: The wavelength conversion member according to claim 1, wherein the matrix is glass.

3: The wavelength conversion member according to claim 1, wherein the phosphor particles absorb part of fluorescence.

4: The wavelength conversion member according to claim 1, wherein the phosphor particles are particles of a garnet-based ceramic phosphor.

5: The wavelength conversion member according to claim 1, containing a light-scattering material.

6: The wavelength conversion member according to claim 1, having a thickness of 1000 μm or less.

7: A light emitting device comprising: the wavelength conversion member according to claim 1; and a light source operable to irradiate the wavelength conversion member with excitation light.

8: The light emitting device according to claim 7, wherein the light source is a light emitting diode or a laser diode.
